(19) United States
(12) Patent Application Publication
(10) Pub. No.: US 2010/0155738 A1
(43) Pub. Date: Jun. 24, 2010

(54) Light Emitting Diode and Method for Manufacturing Same

(76) Inventors: Hiroyuki Nabeta, Tokyo (JP); Hideaki Wakamatsu, Tokyo (JP)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 11/884,398

(22) PCT Filed: Feb. 6, 2006
(86) PCT No.: PCT/JP2006/001968

§ 371 Date: Aug. 15, 2007

(30) Foreign Application Priority Data
Feb. 22, 2005 (JP) 2005-045851

(51) Int. Cl. H01L 33/00

(52) U.S. Cl. 257/76; 438/46; 257/103; 257/E33.025; 257/E33.064

(57) ABSTRACT

This invention provides a light emitting diode in which a thick transparent conductive electrode is formed on an emitting side of GaN based semiconductor light emitting element, and a light emitting efficiency of the GaN semiconductor light emitting element is improved. Further, it provides a manufacturing method of the light emitting diode by which a thick transparent electrode film of the light emitting diode is effectively formed. A light emitting diode which emits light in a blue or an ultraviolet region comprising a substrate and a light emitting layer thereon comprising at least an n-type GaN based semiconductor layer, a p-type GaN based semiconductor layer, and a GaN based semiconductor sandwiched between them, wherein a transparent conductive film having a thickness of 1-100 μm is provided on the light emitting layer.

### TECHNICAL FIELD

The present invention relates to a GaN based light emitting diode which exhibits excellent light emitting efficiency, a white light emitting light emitting diode using the same, and a manufacturing method thereof.

### BACKGROUND OF THE INVENTION

A GaN based light emitting diode composed of a GaN based semiconductor layer enables realization of a white LED via applying a phosphor layer thereon, is applicable to backlight, and is receiving attention as a light source element for illumination.

The basic structure of GaN based semiconductor light emitting elements is a p-n junction diode, constituted in such a way that a light emitting layer is sandwiched between an n-type GaN based semiconductor layer and a p-type GaN based semiconductor layer. During light emission, electrons are injected into the light emitting layer, from an n type GaN based semiconductor layer, while holes are injected from a p-type GaN based semiconductor layer, followed by light emission via recombination in the light emitting layer.

Heretofore employed in GaN based light emitting diodes have been translucent electrodes composed of a thin film of Ni—Au based alloy (refer, for example, to Patent Document 1). However, even though the thickness of the Ni—Au alloy film is reduced, the resulting light transmittance reaches at most about 60% due to the fact that the Ni—Au based alloy film is a metallic film. The above has been one of the reasons for decreased emission efficiency of light emitting diodes.

In order to overcome the above drawback, proposed is a transparent electrode composed of ZnO (refer, for example, to Patent Document 2). By employing the ZnO transparent electrode, it is possible to increase light transmittance to about 80%, so that the emission efficiency of light emitting diodes is significantly improved.

At present, however, the production method for ZnO transparent electrodes is the MBE (Molecular Beam Epitaxy) method, which exhibits the problem in which it is only possible to prepare a thin layer of at most about 0.5 μm. If it is possible to increase the thickness of the transparent electrode, light from the light emitting layer is outputted not only from the top of the element but also from side edges of the element, whereby light emission efficiency is improved (refer, for example, to Patent Document 1). Further, the film forming rate of the MBE method is very slow, being as low 1 μm per hour. Consequently, a production method has been sought which enables the formation of a thick film at a high film production rate.
Patent Document 1: Japanese Patent Publication Open to Public Inspection (hereinafter referred to as JP-A) No. 5-291621
Patent Document 2: JP-A No. 2004-266258
Non-Patent Document 1: Light-Emitting Diodes, edited by E. F. Schubert, Cambridge University Press, 2003, or Nikkei Electronics, page 143 of the issue 2004 Sep. 13.

### SUMMARY OF THE INVENTION

### Problems to be Dissolved by the Invention

An object of the present invention is to provide a light emitting diode which enhances the light emitting efficiency of a GaN based semiconductor light emitting element via formation of a thick transparent conductive film on the light emitting side of a GaN based semiconductor light emitting element to solve the above problem in conventional technologies. Another object is to provide a production method of a light emitting diode, which enables efficient formation of the thick transparent conductive film of light emitting diodes.

### Means to Solve the Problems

The inventors of the present invention conducted various investigations. As a result, it was discovered that the objects of the present invention were achieved employing the following embodiments. In the following, the light emitting diode described in Item 1 is designated as a first light emitting diode of the present invention, while the light emitting diode described in Item 4 is designated as a second diode of the present invention. Further, the first and second light emitting diodes of the present invention are generally designated as the light emitting diodes of the present invention.

The first light emitting diodes of the present invention are those which emit light in the blue or ultraviolet region, and are characterized in incorporating a substrate having a light emitting layer thereon comprising at least an n-type GaN based semiconductor layer, a p-type GaN based semiconductor layer, and a GaN based semiconductor layer sandwiched between them, as well as a transparent conductive film having a thickness of 1-100 μm on the above light emitting layer.

In the present invention, the thickness of the above transparent conductive film is preferably 2-50 μm. Further, it is more preferable that the above transparent conductive film is composed of zinc oxide.

The second light emitting diode of the present invention is one which emits white light. It is characterized in incorporating the above first light emitting diode of the present invention and a phosphor film which absorbs at least some of light emitted by the above diode and emits light at wavelengths which are longer than that of the above emitted light.

The transparent conductive film related to the light emitting diode of the present invention may be formed via plasma spraying.

Further, it is also possible to form the transparent conductive film related to the light emitting diode of the present invention, employing an aerosol deposition method.

Heretofore, the above aerosol deposition method and the plasma spraying method have not been employed as a production method of the transparent conductive film as described in the present invention. For example, “Saishin Tomei Dendo Maku Doko (Trend of the Newest Transparent Conductive Films)” published by Joho Kiko (January 2005) ISBN: 4-901677-33-0, which is a typical technical reference book, lists, as a transparent electrode preparation method, nine methods including a sputtering method, an ion plating method, a PLD method (ablation), a CDV method, a spray heat decomposition method, a sol-gel method, a dip coating method, a coating heat decomposition method, and a screen printing method.

Obviously, it is not easy even for a person skilled in the art to use the aerosol deposition method or the plasma spraying method to prepare the transparent conductive film. However, at this time, from the necessity to prepare a relatively thick transparent conductive film, the aerosol deposition method and the plasma spraying method were investigated. As a result, it was discovered that it was possible to form a 1-100 μm thick film exhibiting still higher transparency, which was hardly be prepared via conventional methods.

Additional features of the aerosol deposition method and the plasma spraying method include a high film casting rate, low facility cost due to use of a low vacuum system, and no use of solvents/binder resins.

### EMBODIMENTS

Based on the present invention, it is possible to provide a light emitting diode in such a way that a thick transparent conductive film is formed on the light emitting side of a GaN based semiconductor light emitting element, and the light emitting efficiency of the above GaN based semiconductor light emitting element is enhanced.

The reason for this is that it is possibly to form an excellent transparent conductive film which is compatible with electric conductivity and light transmittance. Further, based on the production method of the light emitting diode of the present invention, it is possible to efficiently produce a thick transparent conducive film.

### BRIEF DESCRIPTION OF THE DRAWINGS

FIG. 1 is a schematic structural view of the aerosol/deposition film casting apparatus employed in the present invention.

FIG. 2 is a view showing aspects of the structure of a white LED and the production process thereof.

### DESCRIPTION OF THE NUMERAL DESIGNATIONS

4 aerosolizing chamber
2 and 6 piping
3 and 5 valve
8 nozzle
9 holder
10 blue LED laminated body
11 XYZθ stage
12 minute particle raw material
21 transparent conductive film
22 inner lead
23 mounting lead
24 phosphor
25 epoxy resin

### THE BEST EMBODIMENT FOR EMBODYING THE INVENTION

Further detailed will be blue light emitting diodes (hereinafter referred to as the blue LEDs of the present invention, specifically including those emitting ultraviolet radiation) which are first light emitting diodes of the present invention, white light emitting diodes (hereinafter referred to as white LEDs of the present invention) which are the second light emitting diodes of the present invention, and production methods thereof.

Blue LEDs of the present invention are preferably GaN based compound semiconductors. A light emitting element employing the GAN based compound semiconductor is prepared in such a way that GaN based semiconductors, such as INGaN, are applied onto a substrate to form a light emitting layer, employing the MOCVD method. Structures of the light emitting elements include a homo-structure and a hetero-structure incorporating an MIS junction, a PIN junction, or a PN junction, as well as a double hetero-structure. It is possible to select any of the appropriate light emitting wavelengths depending on the materials of the semiconductor layer and mixing degree of crystals.

Further, it is possible to form a thin semiconductor active layer in a single quantum well structure or a multiple quantum well structure so that the quantum effect occurs. Specifically, in the present invention, by structuring the active layer of the light emitting element in the single quantum well structure of INGaN, use is applicable as a light emitting diode which results in light emission at relatively high luminance.

When GaN based compound semiconductors are employed, it is possible to employ materials such as sapphire, spinel, SiC, Si, or ZnO as a substrate. However, in order to form gallium nitride of desired crystallinity, it is preferable to employ a sapphire substrate.

The GaN based semiconductor layer is formed on such a sapphire substrate so that the PN junction is formed via a buffer layer such as GaN or AlN. GaN based semiconductors in a non-impurity doped state exhibit n-type conductivity. In order to form n-type GaN based semiconductors which exhibit desired characteristics (including carrier concentration) such as enhancement of light emitting efficiency, it is preferable that any of Si, Ge, Se, Te and C as an n-type dopant are appropriately doped. On the other hand, when p-type GaN based semiconductors are formed, any of Zn, Mg, Be, Ca, Sr, and Ba, each of which is a p-type dopant, are doped. Since it is difficult to convert the GaN based compound semiconductors to the p-type only via doping with p-type dopants, it is preferable that after introduction of the p-type dopants, conversion to the p-type is carried out employing a furnace, as well as exposure to low rate electron beam or exposure to a plasma.

Subsequently, after the surface of p-type and n-type GaN based semiconductors is exposed via etching, a transparent conductive film in the desired shape is formed on each of the semiconductor layers, employing the aerosol deposition method or the plasma spraying method.

In the present invention, the above basic structure can be constituted employing any of the conventionally used methods. A product which has undergone the above process but is not subjected to formation of a transparent conductive film is hereinafter called a laminated product during blue LED production. A product, in which a transparent conductive film is formed during blue LED production, is the blue LED of the present invention. A product on which a phosphor film is provided so that as a whole, white light is emitted is the white LED of the present invention.

Transparent inorganic oxides are employed in the transparent conductive film of the present invention. Transparent inorganic oxides usable in the present invention include zinc oxide, ITO (indium tin oxide), and tin oxide. Of these, zinc oxide is preferred as an inorganic oxide. The reason for that is that it is possible to realize high transparency by employing zinc oxide as a transparent conductive film. Further, a features of zinc oxide is less expensive then ITO which has been widely employed. Further, depletion of indium sources is a major concern. Further, if desired, inorganic oxides doped with metals such as Ga or Al may be employed.

The thickness of the transparent conductive film of the present invention is typically 1-100 μm. When the thickness of the transparent conductive layer is less than 1 μm, a problem occurs in which the eclectic resistance of the transparent conductive layer increases, while when it exceeds 100 μm, a problem occurs in which its transparency decreases. In the present invention, the thickness of the transparent conductive layer is preferably in the range of 2-50 μm. The reason for that is that the electric resistance and the transparency which are incompatible with each other fall within the optimal range.

In the present invention, the transparent conductive film is formed employing a so-called aerosol-deposition method in which minute transparent inorganic oxide particles, as a raw material, are subjected to a high rate of collision onto the laminated body during blue LED production.

As a film casting apparatus, employed may be embodiments disclosed on page 44 of “Oyo Butsuri (Applied Physics)” Volume 68, No. 1 as well as JP-A No. 2003-215256.

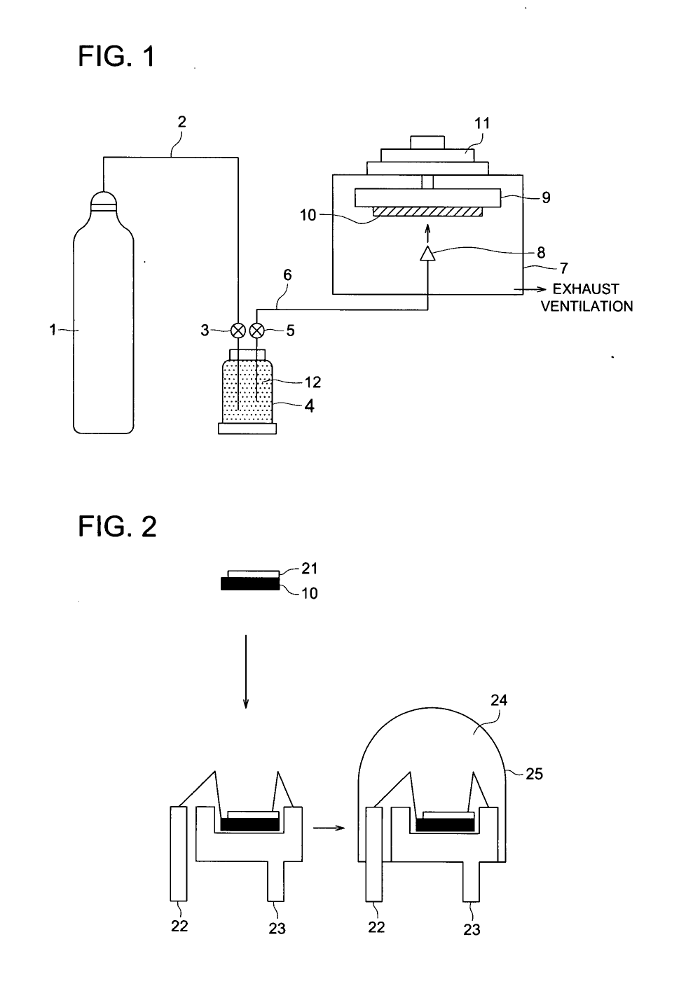

FIG. 1 is a schematic view showing the structure of the aerosol-deposition film casting apparatus employed in the present invention. The aerosol-deposition film casting apparatus is composed of holder 9 which secures laminated body 10 during blue LED production, XYZθ stage 11 which three-dimensionally drives holder via XYZθ, nozzle 8 provided with narrow apertures which blow off minute particle raw material 12 onto laminated body during blue LED production, chamber 7 provided with piping 6 which connects nozzle 8 to aerosolizing chamber 4, and high pressure gas steel cylinder which stores the carrier gas, aerosolizing chamber 4 in which minute particle raw material 12 and the carrier gas are blended while stirring, and piping 2 which connects them. On the reverse surface of XYZθ stage 11, a temperature controlling mechanism (not shown) employing a Peltier element is arranged so that laminated body 10, during blue LED production, can be maintained at an optimal temperature.

Further, by employing minute particle raw material 12 in aerosolizing chamber 4, laminated body 10, during blue LED production, is formed employing the following procedures.

Minute particle raw material 12 at a preferable particle diameter of 0.02-5 μm, but more preferably 0.1-2 μm, which is placed in aerosolizing chamber 4 is subjected to vibration and agitation together with carrier gases introduced into aerosolizing chamber 4 via piping from high pressure gas cylinder 1 which stores the carrier gases, whereby an aerosol is prepared.

The diameter of particles employed as a minute particle raw material is determined employing common laser diffraction system particle size meters. Specific examples include HELOS (produced by JEOL Co.), MICROTRAC HRA (produced by Nikkiso Co., Ltd.), SALD-1100 (produced by Shimadzu Corp.), and COULTER COUNTER (produced by Coulter Co.). Of these, NICROTRAC HRA is specifically preferred.

Aerosolized minute particle raw material 12 passes through piping 6 and is sprayed onto laminated body 10 during blue LED production, together with a carrier gas from nozzle 8 having a narrow orifice in chamber 7, whereby a coating is formed. Chamber 7 is exhausted using a vacuum pump, and the degree of vacuum in chamber 7 is adjusted as optimal. According to the present invention, the degree of vacuum is preferably 0.01-10,000 Pa, but is more preferably 0.1-1,000 Pa. Further, since XYZθ stage 11 enables the substrate holder to move three-dimensionally, a transparent conductive film having a required thickness may be formed on a predetermined position of laminated body 10 during blue LED production. If desired, it is possible to apply a sealing layer onto the transparent conductive film formed on laminated body 10 during blue LED production.

Aerosolized minute particle raw material 12 is conveyed by a carrier gas at a preferable flow rate of 100-400 m/second, and accumulates on laminated body 10 during blue LED production via collision therewith. Minute particle raw material 12, conveyed by the carrier gas, forms a film via junction induced by mutual collision impact.

In the production method of the present invention, it is preferable to employ an inert gas such as nitrogen gas or helium gas as a carrier gas to be used in accelerating and ejecting a minute particle raw material. Nitrogen gas may more preferably be employed.

Further, it is preferable to maintain the temperature of a laminated body, with which the minute particle raw material is allowed to collide during blue LED production, in the range between −100° C. and 200° C. When the laminated body during blue LED production is heated to a temperature exceeding approximately 200° C., the resulting film becomes hazy, whereby luminance of a blue LED occasionally decreases due to low transmission of light.

Laminated bodies during blue LED production usable in the present invention are preferably InₓGa₁₋ₓN based, which exhibit an emission peak wavelength of blue LED of 480-440 nm.

Further, another preferred embodiment regarding a production method of a transparent conductive film will now be described. A so-called plasma spraying method is available in which minute particles of transparent inorganic oxides are melted via plasma, ejected, and fused onto a laminated body during blue LED production.

It is preferable to employ APS-7000 (produced by Aeroplasma Corp.), PLAZJET (produced by TAFA, Inc.), or TRIPLEX II (produced by Sulzer Metco Ltd.) as a plasma spraying apparatus. Of these, APS-7000 produced by Aeroplasma Corp., described in JP-A No. 2001-3151, is most preferably employed.

Preferred ranges of the parameters during formation of the transparent conductive film are as follows:
Powder particle diameter: 10-100 μm
Plasma gas flow rate: 1-200 L/minute
Plasma output: 10-200 kW
Carrier gas flow rate: 1-20 L/minute
Spray distance: 10-200 mm
Powder supply rate: 1-100 g/minute
Preheat (temperature of a laminated body during blue LED production prior to spraying): 10-200° C.

A white LED of the present invention is completed by use of a chip of a produced LED emitting diode forming a transparent conductive film, for example, by attaching a transparent resin such as silicone resin or a glass cap to the front surface of the emitting chip and by attaching a formed phosphor film part thereto. It is possible for an emitting diode of the present invention to emit blue or white light via loading a rated direct current up to a maximum of 30 mA at 5 V.

A phosphor film is utilized which absorbs at least some of light emitted from an emitting diode of the present invention, and emits light of a longer wavelength than that of the absorbed light. Examples of usable phosphors according to the present invention include a sapphire activated by chromium, a (Y,Gd,Ce)₃Al₅O₁₂ phosphor, and erbium oxide (3). Of these, the (Y,Gd,Ce)₃Al₅O₁₂ phosphor is preferable.

A constitution of a white LED of the present invention and a production process thereof are illustrated in FIG. 2.

Initially, during blue LED production, transparent conductive film 21 is formed on laminated body 10, followed, by wire-bonding inner lead 22 and laminated body 10 during blue LED production, and by wire-bonding mount lead 23 and transparent conductive film 21. Subsequently, the white LED of the present invention is finally prepared by filling phosphor 24 over the resulting product, followed by sealing with epoxy resin 25.

### EXAMPLES

To detail the above embodiments, the constitution and the effects of the present invention will be described specifically by referring to typical examples of the present invention, however, as a matter of course, the embodiments of the present invention are not limited thereto.

### Preparation of Light Emitting Diode Samples

### Comparative Example 1

A GaN based compound semiconductor was subjected to film formation via the MOCVD method by allowing TMG (trimethyl gallium) gas, TMI (trimethyl indium) gas, nitrogen gas, and a dopant gas together with H₂ carrier gas to flow onto a washed sapphire substrate.

During film formation, GaN based n- and p-type conductive semiconductors were each formed by exchanging SiH₄ for Cp₂Mg (cyclopentadienyl magnesium) as a dopant gas during film formation. This blue LED element was provided with a contact layer (a semiconductor layer for electrically bonding an electrode and a semiconductor), being a GaN based n-type conductive semiconductor; a cladding layer (a semiconductor layer with a wide band gap to enclose light and a carrier), being a gallium aluminum nitride semiconductor of p-type conductivity; and a contact layer, being a GaN based semiconductor layer of p-type conductivity, wherein an active layer (an emitting layer), composed of a non-doped InGaN for constituting a single quantum well structure at a thickness of about 3 mm between the n-type conductive contact layer with and the p-type conductive cladding layer, is formed. In addition, a GaN based semiconductor layer, serving as a buffer layer, was formed on the sapphire substrate at a low temperature. Further, the p-type GaN based semiconductor was annealed at a temperature of at least 400° C. after film formation.

By sputtering, a Ga-doped ZnO transparent conductive film was formed on the contact layer, being a GaN based semiconductor layer of p-type conductivity. The resulting film thickness was 0.5 μm.

Further, by sputtering, metal electrodes were formed on each of the contact layers. An LED chip with a 350 μm square shape was formed as an emitting element by scribing lines on the finished semiconductor wafer, followed by dividing by an external force.

On the other hand, a mounted lead cup, into the LED chip was placed, was formed by punching out a metal plate. The LED chip was mounted in the cup using an epoxy resin, followed by electrically bonding by allowing each the electrodes to be wire-bonded to the mounted lead and the inner lead using gold wire as a conductive wire.

Further, to protect the LED chip from external stress, moisture, and dust, a lead terminal was placed in an empty shell-shaped casting case. A transparent epoxy resin was cast into the casting case, followed by curing at 150° C. over 5 hours. In such a manner, a light emitting diode, which became the light emitting device shown in FIG. 2, was prepared (however, in this case, a phosphor was not filled).

### Example 1

A Ga-doped ZnO transparent conductive film was formed on a contact layer, being a GaN based semiconductor of p-type conductivity, via an aerosol deposition film formation apparatus. During blue LED production, a 10 μm thick film was formed on a laminated body by spraying Ga-doped ZnO particles, of a particle size distribution of 0.1-1 μm and an average particle diameter of 0.5 μm, filled-in an aerosolizing chamber, being the same as in the comparative example, by use of N₂ gas as a carrier gas at a flow rate of 200 m/sec, wherein the degree of vacuum of the chamber was 100 Pa and the substrate temperature was 20° C.

Further, a light emitting diode was prepared via preparing a blue LED chip of the present invention in the same manner as in Comparative Example 1.

### Example 2

A Ga-doped ZnO transparent conductive film was formed by plasma spraying on a contact layer, being a p-type conductive GaN based semiconductor. An APS-7000 plasma spraying apparatus (produced by Aeroplasma Corp.) and Ga-doped ZnO particles, of a particle size distribution of 10-30 μm and an average particle diameter of 20 μm, were employed in this plasma spraying.

The spray conditions follow:

Oxygen plasma gas flow rate: 50 L/minute

Plasma output: 60 kW

Powder carrier gas flow rate: 6 L/minute

Spray distance: 60 mm

Powder supply rate: 20 g/minute

Preheating temperature: 150° C.

During blue LED production, a 10 μm thick film was formed on a laminated body by spraying Ga-doped ZnO particles, being the same as in Comparative Example 1, under those conditions.

Further, a light emitting diode was produced by preparing a blue LED chip of the present invention in the same manner as in Comparative Example 1.

### Comparative Example 2

An LED chip, having been obtained in the same manner as in Comparative Example 1, was subjected to adhesion to a mounting lead to be bonded.

A liquid mixture was prepared employing an epoxy resin of a (Y,Gd,Ce)₃Al₅O₁₂ phosphor (NT8014, produced by Nitto Denko Corp.) and an acid anhydride based curing agent.

After 50 μl of the above liquid mixture of the phosphor and resin was dripped onto an LED chip employing a syringe and dried, whereby a white light emitting diode was prepared by shell-type casting in the same manner as for Comparative Example 1.

### Example 3

After an LED chip of the present invention, having been obtained in the same manner as for Example 1, was subjected to adhesion to a mounted lead to result in bonding, a phosphor layer was formed in the same manner as in Comparative Example 2.

Further, a white light emitting diode of the present invention was prepared by shell-type casting in the same manner as in Comparative Example 1.

### Example 4

After a blue LED chip of the present invention, having been obtained in the same manner as in Example 2, was subjected to adhesion to a mount lead to reset in bonding, a phosphor layer was formed in the same manner as in Comparative Example 2. Further, a white light emitting diode was made by shell-type casting in the same manner as in Comparative Example 1.

### Comparative Examples 3-5

Light emitting diodes of Comparative Examples 3-5 were prepared in the same manner as in Comparative Example 1 except that preparation was carried out under the preparing conditions shown in Table 1.

### Comparative Examples 6-8

White light emitting diodes of Comparative Examples 6, 7, and 8 were prepared, each corresponding respectively to those of Comparative Examples 3, 4, and 5, in the same manner as in Comparative Example 2 (refer to Table 2).

### Examples 5-13

Blue light emitting diodes of Examples 5-13 were prepared in the same manner as in Comparative Example 1 except that preparation was carried out under the preparing conditions shown in Table 1.

### Examples 14-22

Blue light emitting diodes of Examples 14-22 were prepared, each corresponding to those of Comparative Examples 14-22, in the same manner as in Comparative Example 3 (refer to Table 2).

### (Performance Evaluation)

Relative values of the initial light flux were evaluated by driving the light emitting diodes, prepared as above, at 50° C. and 20 mA. Tables 1 and 2 show the results.

TABLE 1

| | | | | | Film |
|---|---|---|---|---|---|
| | Con- | | Film | Initial | Forming |
| | ductive | Film Forming | Thickness | Light | Rate |
| | Film | Method | (μm) | Flux | (μm/min) |
| Comparative | ZnO | Sputtering | 0.50 | 1.00 | 0.1 |
| Example 1 | | | | | |
| Example 1 | ZnO | Aerosolization | 10.00 | 1.83 | 5 |
| Example 2 | ZnO | Spraying | 10.00 | 1.70 | 5 |
| Comparative | ZnO | Sputtering | 0.90 | 1.05 | 0.1 |
| Example 3 | | | | | |
| Comparative | ZnO | Sputtering | 101.00 | 0.95 | 0.1 |
| Example 4 | | | | | |
| Comparative | ZnO | Sputtering | 110.00 | 0.82 | 0.1 |
| Example 5 | | | | | |
| Example 5 | ZnO | Aerosolization | 1.00 | 1.38 | 5 |
| Example 6 | ZnO | Aerosolization | 2.00 | 1.66 | 5 |
| Example 7 | ITO | Aerosolization | 10.00 | 1.20 | 5 |
| Example 8 | ZnO | Aerosolization | 50.00 | 1.86 | 5 |
| Example 9 | ZnO | Aerosolization | 60.00 | 1.88 | 5 |
| Example 10 | ZnO | Aerosolization | 100.00 | 1.32 | 5 |
| Example 11 | ZnO | Spraying | 50.00 | 1.70 | 5 |
| Example 12 | ZnO | Sputtering | 10.00 | 1.47 | 0.1 |
| Example 13 | ZnO | Deposition | 10.00 | 1.29 | 0.1 |

TABLE 2

| | | | | | Film |
|---|---|---|---|---|---|
| | Con- | | Film | Initial | Forming |
| | ductive | Film Forming | Thickness | Light | Rate |
| | Film | Method | (μm) | Flux | (μm/min) |
| Comparative | ZnO | Sputtering | 0.50 | 1.00 | 0.1 |
| Example 2 | | | | | |
| Example 3 | ZnO | Aerosolization | 10.00 | 2.11 | 5 |
| Example 4 | ZnO | Spraying | 10.00 | 2.03 | 5 |
| Comparative | ZnO | Sputtering | 0.90 | 1.03 | 0.1 |
| Example 6 | | | | | |
| Comparative | ZnO | Sputtering | 101.00 | 0.96 | 0.1 |
| Example 7 | | | | | |
| Comparative | ZnO | Sputtering | 110.00 | 0.87 | 0.1 |
| Example 8 | | | | | |
| Example 14 | ZnO | Aerosolization | 1.00 | 1.53 | 5 |
| Example 15 | ZnO | Aerosolization | 2.00 | 1.95 | 5 |
| Abureshonn | ITO | Aerosolization | 10.00 | 1.40 | 5 |
| Example | | | | | |
| 16 | | | | | |
| Example 17 | ZnO | Aerosolization | 50.00 | 1.86 | 5 |
| Example 18 | ZnO | Aerosolization | 60.00 | 1.83 | 5 |
| Example 19 | ZnO | Aerosolization | 100.00 | 1.62 | 5 |
| Example 20 | ZnO | Spraying | 50.00 | 1.66 | 5 |
| Example 21 | ZnO | Sputtering | 10.00 | 1.50 | 0.1 |
| Example 22 | ZnO | Deposition | 10.00 | 1.38 | 0.1 |

Evaluations show that each of the light emitting diodes, in the scope of the present invention, exhibits a high value of initial light flux.

In addition, although an attempt to form a ZnO transparent electrode was carried out employing MBE (molecular beam epitaxy), the film forming rate was 0.001 μm/min, resulting in commercial non-viability.

1. A light emitting diode which emits light in a blue or an ultraviolet region comprising a substrate and a light emitting layer thereon comprising at least an n-type GaN based semiconductor layer, a p-type GaN based semiconductor layer, and a GaN based semiconductor sandwiched between them,
wherein a transparent conductive film having a thickness of 1-100 μm is provided on the light emitting layer.

2. The light emitting diode according to claim 1,
wherein a transparent conductive film has a thickness of 2-50 μm.

3. The light emitting diode according to claim 1,
wherein the transparent conductive film is comprised of a zinc oxide.

4. A light emitting diode which emits white light comprising the light emitting diode according to claim 1 and a phosphor film which absorb at least a part of light emitted from the light emitting diode of claims 1-3, and which emits light at wavelengths which are longer than that of the light emitting diode of claim 1.

5. A manufacturing method of the light emitting diode according to claim 1 comprising:
(1) forming a light emitting layer comprising an n-type GaN based semiconductor layer, a p-type GaN based semiconductor layer, and a GaN based semiconductor sandwiched between them, on a substrate, and
(2) providing a transparent conductive film having a thickness of 1-100 μm on the light emitting layers,
wherein the transparent conductive film is formed with a plasma spraying method.

6. A manufacturing method of the light emitting diode according to claim 1 comprising,
(1) forming a light emitting layer comprising an n-type GaN based semiconductor layer, a p-type GaN based semiconductor layer, and a GaN based semiconductor sandwiched between them, on a substrate, and
(2) providing a transparent conductive film having a thickness of 1-100 μm on the light emitting layers,
wherein the transparent conductive film is formed with an aerosol deposition method.
